(19) United States
(12) Patent Application Publication
(10) Pub. No.: US 2020/0321356 A1
(43) Pub. Date: Oct. 8, 2020

(54) ARRAY SUBSTRATE AND DISPLAY DEVICE

(71) Applicants: Beijing BOE Optoelectronics Technology Co., Ltd., Beijing (CN); BOE TECHNOLOGY GROUP CO., LTD., Beijing (CN)

(72) Inventors: Jianxing Shang, Beijing (CN); Min Mao, Beijing (CN); Pengqu Zhang, Beijing (CN)

(21) Appl. No.: 16/303,805

(22) PCT Filed: Apr. 13, 2018
(86) PCT No.: PCT/CN2018/083041

§ 371 Date: Nov. 21, 2018

(30) Foreign Application Priority Data
Apr. 14, 2017 (CN) 201710245108.0

(51) Int. Cl. H01L 27/12; G02F 1/1362; G02F 1/1368; G02F 1/1345

(52) U.S. Cl. CPC H01L 27/124; G02F 1/136286; H01L 27/3276; G02F 1/13454; G02F 1/1368

(57) ABSTRACT

The present disclosure provides an array substrate and a display device. The array substrate includes a plurality of thin film transistors, each of the plurality of thin film transistors including a gate layer, a source/drain layer and a gate insulating layer. The source/drain layer is provided above the gate layer, and the gate insulating layer is provided between the gate layer and the source/drain layer. A via hole platform in the gate insulating layer and above the gate layer of one of the plurality of thin film transistors is arranged to at least partially overlap a via hole platform in the source/drain layer of another of the plurality of thin film transistors.

### CROSS-REFERENCE TO RELATED APPLICATIONS

The present disclosure is based on International Application No. PCT/CN2018/083041 filed on Apr. 13, 2018, which claims priority to Chinese Patent Application No. 201710245108.0, filed on Apr. 14, 2017, the entire contents thereof are incorporated herein by reference.

### TECHNICAL FIELD

The present disclosure relates to the field of display technology, and in particular, to an array substrate and a display device.

### BACKGROUND

A thin film transistor liquid crystal display (TFT-LCD) is a common liquid crystal display product at present. In the TFT-LCD, each pixel is generally provided with a thin film transistor, and the thin film transistor of each pixel needs to be coupled with a corresponding gate drive circuit to control the change of transmittance of the liquid crystal in the pixel, and thus to control the change in the pixel color. A gate driver on array (GOA) circuit technology is a commonly used gate drive circuit technology in the TFT-LCD at present. In this technology, the gate drive circuit is directly formed on the array substrate, in order to eliminate the gate drive integrated circuit, thus reducing the cost.

The array substrate generally includes a GOA region and a display region (AA region). In the GOA region, it is necessary to couple a gate line to the source/drain metal layer by forming a via hole penetrated through a gate insulator (GI) layer; while in the display region, it is also necessary to couple the drain electrode or the source electrode of the TFT to the pixel electrode by forming a via hole.

### SUMMARY

The present disclosure provides an array substrate and a display device.

Other features and advantages of the present disclosure will be apparent from the following detailed description, or may be learned in part by practice of the present disclosure.

According to an aspect of the present disclosure, an array substrate is provided. The array substrate includes a plurality of thin film transistors. Each of the plurality of thin film transistors includes a gate layer, a source/drain layer and a gate insulating layer. The source/drain layer is provided above the gate layer, and the gate insulating layer is provided between the gate layer and the source/drain layer. A via hole platform in the gate insulating layer and above the gate layer of one of the plurality of thin film transistors is arranged to at least partially coincide with a via hole platform in the source/drain layer of another of the plurality of thin film transistors.

In an exemplary arrangement of the present disclosure, the via hole platform is a metal base.

In an exemplary arrangement of the present disclosure, the via hole of the source/drain layer includes at least one first via hole.

In an exemplary arrangement of the present disclosure, the array substrate further includes a passivation layer disposed on the source/drain layer. The passivation layer includes at least one second via hole, and the at least one first via hole and the at least one second via hole form a sleeve hole structure.

In an exemplary arrangement of the present disclosure, a diameter of the at least one second via hole is larger than a diameter of the at least one first via hole.

In an exemplary arrangement of the present disclosure, the gate insulating layer includes at least one third via hole. The at least one third via hole and the at least one second via hole are formed of the same mask plate.

In an exemplary arrangement of the present disclosure, the gate insulating layer and the passivation layer are made of the same non-metal material.

In an exemplary arrangement of the present disclosure, the array substrate further includes a conductive film covering the source/drain layer and the sleeve hole structure for electrically connecting the gate layer and the source/drain layer.

In an exemplary arrangement of the present disclosure, the at least one first via hole and the at least one second via hole are in the shape of an inverted round cone.

In an exemplary arrangement of the present disclosure, the thin film transistor is provided in the GOA region of the array substrate.

According to an aspect of the present disclosure, a display device including the array substrate of any of the above arrangements is provided.

The above general description and the following detailed description are intended to be illustrative and not restrictive of the present disclosure.

### BRIEF DESCRIPTION OF THE DRAWINGS

The accompanying drawings are incorporated in and constitute part of the specification, show the arrangements of the present disclosure and are intended to explain the principle of the present disclosure together with the description. It is apparent that the accompanying drawings in the following description are only some of the arrangements of the present disclosure, and other drawings may be obtained from these accompanying drawings by those skilled in the art without any creative work.

FIG. 1 shows a schematic view of an array substrate in the related art in an exemplary arrangement of the present disclosure.

FIG. 2 shows a schematic view of a gate layer in an exemplary arrangement of the present disclosure.

FIG. 3 shows a top view of an array substrate in an exemplary arrangement of the present disclosure.

FIG. 4 is a cross-sectional view of the array substrate shown in FIG. 3.

FIG. 5 shows a top view of another array substrate in an exemplary arrangement of the present disclosure.

FIG. 6 shows a cross-sectional view of the array substrate shown in FIG. 5.

FIG. 7 shows a cross-sectional view of still another array substrate in an exemplary arrangement of the present disclosure.

FIG. 8 shows a schematic view of a display device in an exemplary arrangement of the present disclosure.

### DETAILED DESCRIPTION

Example arrangements will now be described more fully with reference to the accompanying drawings. However, the example arrangements can be embodied in a variety of forms, and should not be construed as limitation of the examples set forth herein; the described features, structures, or characteristics may be combined in one or more arrangements in any suitable manner. In the following description, numerous specific details are provided in order to fully understand the arrangements of the present disclosure. However, those skilled in the art will appreciate that one or more of specific details may be omitted when technical solutions of the present disclosure is implemented, or other methods, components, devices, blocks, etc. may be employed.

It should be noted that, in the drawings, dimensions of layers and regions may be exaggerated for clarity of illustration. It should be also understood that, when an element or layer is referred to as being “on” another element or layer, it may be directly on the other element or an intermediate layer may be present therebetween. In addition, it should be understood that, when an element or layer is referred to as being “under” another element or layer, it may be directly under other elements or more than one intermediate layer or element may be present therebetween. In addition, it should also be understood that, when a layer or element is referred to as being “between” two layers or two elements, it may be a single layer between two layers or two elements, or more than one intermediate layer or element may be present. Like reference numbers indicate like elements throughout.

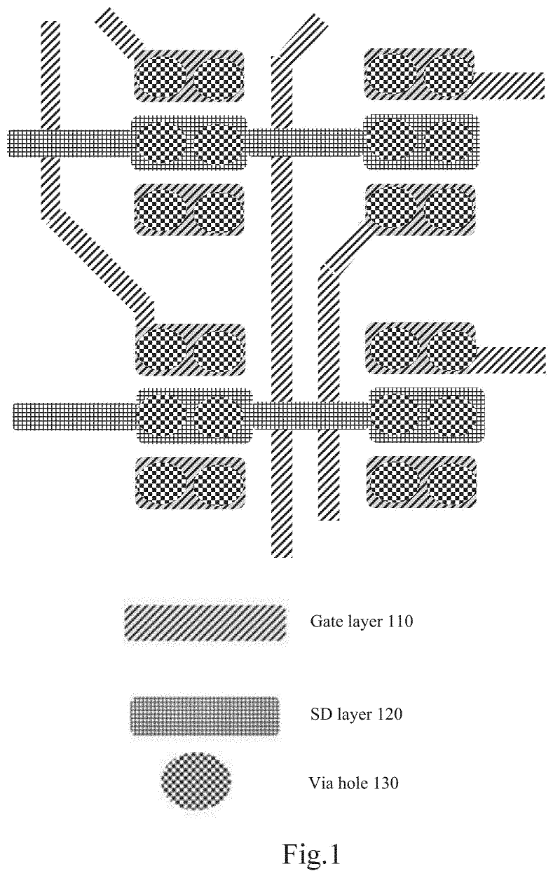

FIG. 1 shows a schematic view of an array substrate in the related art.

As shown in FIG. 1, the array substrate 100 includes a gate layer 110, a source/drain layer (SD layer) 120 and a GI layer (not shown) between the gate layer and the SD layer. A via hole 130 connecting the SD layer to the gate layer is formed by exposing and etching above the GI layer and the SD layer.

Referring to FIG. 1, the figure schematically shows relative positions of a via hole platform of the gate layer and a via hole platform of the SD layer. As one example, FIG. 1 shows eight via hole platforms of the gate layer and four via hole platforms of the SD layer, and the via hole platform of the gate layer and the via hole platform of the SD layer are separately disposed (i.e., without any overlap). The via hole platform refers to a metal base in the layer for electrical connection. In the manufacturing process of the display panel, the array substrate (TFT substrate) and a color filter substrate (CF substrate) are oppositely bonded together to form a cell by cell process, and a specific process thereof is to apply a frame adhesive on a periphery of the TFT substrate and the CF substrate and then cure the frame adhesive by ultraviolet (UV) light, so as to bond the TFT substrate and the CF substrate together. Since the via hole platform made of metal material is opaque to UV light and thus reflection will occur, a UV transmittance is lowered when the number of via hole platforms is large, thus leading to an elongated UV curing time.

An arrangement of the present disclosure provides an array substrate including a plurality of thin film transistors (TFTs), each of the plurality of thin film transistors including a gate layer and a source/drain layer (SD layer). The source/drain layer is provided above the gate layer. The thin film transistor further includes a GI layer between the source/drain layer and the gate layer, and a passivation layer above the SD layer. The via hole platform above the gate layer of one of thin film transistors (i.e., the via hole platform in the GI layer) is arranged to at least partially overlap with the via hole platform in the source/drain layer of another thin film transistor. By at least partially overlapping the via hole platform above the gate layer of one of thin film transistors with the via hole platform in the SD layer of another thin film transistor, the number of via hole platforms of the array substrate is reduced, thus reducing an area occupied by the metal base which blocks UV light, so that the UV light transmittance can be increased and the UV curing time can be shorten.

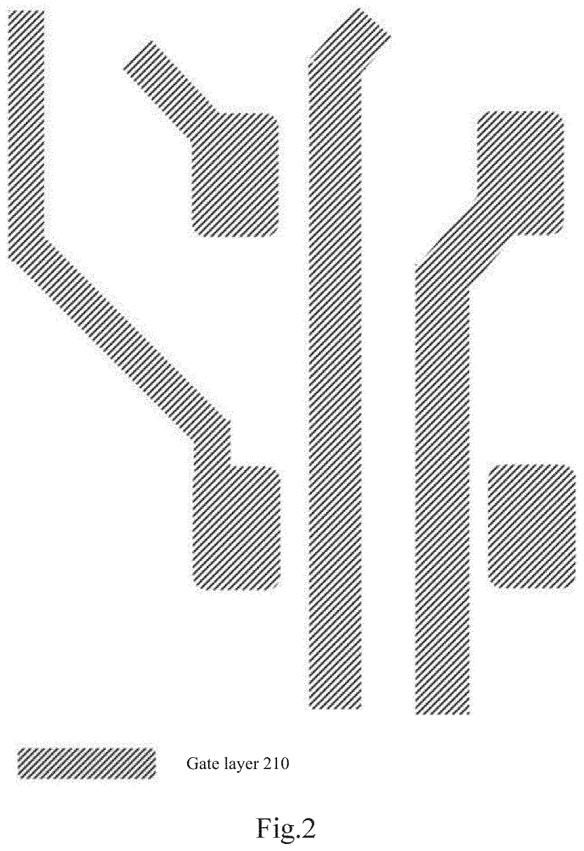

FIG. 2 shows a schematic view of a gate layer 210 in an exemplary arrangement of the present disclosure.

The gate metal may be deposited on a base and etched to form a gate layer of the TFT.

The specific etching process can adopt the existing method, and will not be described in detail herein.

In an exemplary arrangement, the gate layer may be a metal compound conductive layer formed of a plurality of layers of metal. The gate layer may be made of a material such as aluminum or aluminum alloy, or a metal compound conductive layer formed by stacking an aluminum layer, a tungsten layer and a chromium layer. Alternatively, a metal molybdenum Mo or a molybdenum Mo/aluminum Al/molybdenum Mo may be used to form the gate layer. The Mo/Al/Mo is a three-layer metal, two layers of Mo serve as protective layers, and one layer of Al serves as a conductive layer. However, this will not be defined by the present disclosure.

In an exemplary arrangement, the base may be a glass substrate. The glass substrate is uniform in material, has high transparency and low reflectivity, and has good thermal stability, thus maintaining stable properties after repeatedly performing high temperature process. Since there are many chemicals used in the TFT manufacturing process, the glass substrate needs to have good chemical resistance. The glass substrate also needs to have sufficient mechanical strength, good precision machining characteristics, and excellent electrical insulation properties.

Referring to FIG. 2, a main body of the gate layer is similar to the related art shown in FIG. 1, but the structure in the arrangement of the present disclosure is employed to reduce the number of via hole platforms and thus appropriately increase the width of trace. The so-called appropriate increase herein needs to be designed according to the actual situation. For example, on the one hand, the strength of the Electro-Static discharge (ESD) capability of the array substrate and the ESD requirements thereof may be considered; on the other hand, the UV transmittance requirement of the array substrate may also be considered.

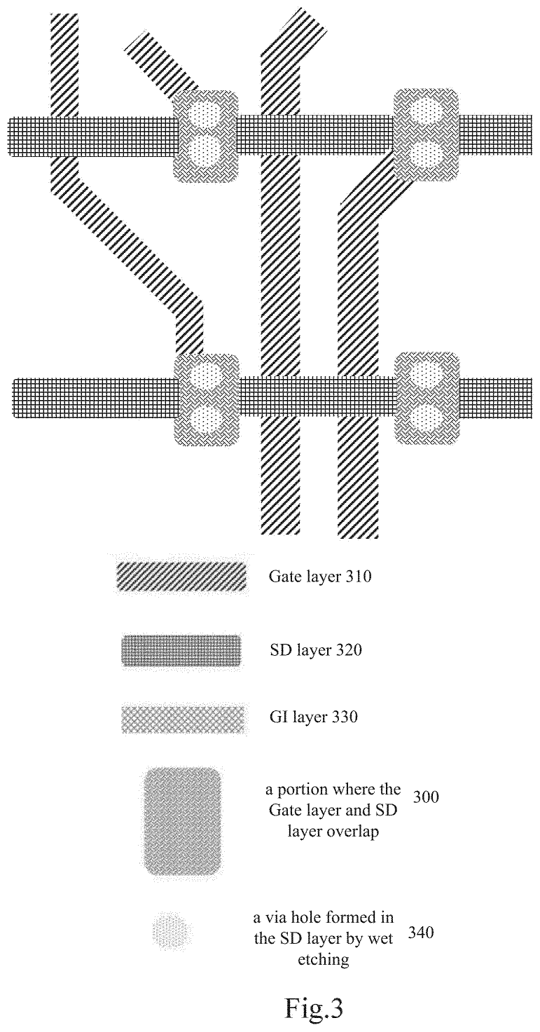

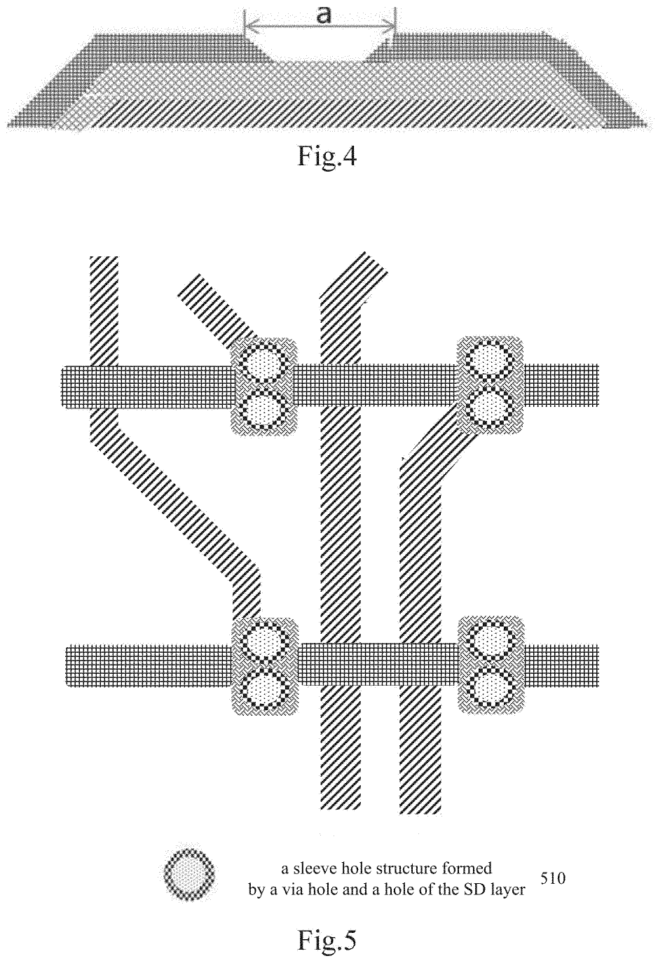

FIG. 3 shows a top view of an array substrate in an exemplary arrangement of the present disclosure. FIG. 4 is a corresponding cross-sectional view of at least a portion of the array substrate of FIG. 3.

As shown in FIG. 3, a via hole platform is disposed at an overlapping position 300 of at least one gate layer 310 and an SD layer 320, i.e., a via hole platform above the gate layer (in a GI layer 330) in FIG. 1 is overlapped with a via hole platform in the SD layer. A via hole 340 is formed in the SD layer by wet etching. With the above design applied, eight via hole platforms shown in FIG. 1 only need to occupy an area for four via hole platforms due to the two-two overlap arrangement, and the area occupied by the via hole platform of the array substrate is reduced compared with that of FIG. 1.

It should be noted that although the via hole platform above the gate layer and the via hole platform in the SD layer are completely overlapped in FIG. 3 as an example, in other arrangements, the partial overlap arrangement may also be used. However, this will not be defined by the present disclosure.

Referring to FIG. 4 (while using the same references in FIG. 3), the gate insulating layer (GI) layer 330 is deposited on the gate layer 310. The source/drain layer 320 of the TFT is deposited on the GI layer to form a SD layer. The gate insulating layer is overlaid on the gate layer, and the gate insulating layer may be one layer formed of SiO, SiN or AlO, and the thickness thereof is, for example, about 175-300 nm. Of course, the gate insulating layer may also be two layers. The first layer thereof is a SiO₂ film. In order to improve quality of the film, a second layer of SiNx is added to the SiO₂ film.

In an exemplary arrangement, the SD metal may be deposited and etched using a sputtering technique.

The via hole is also called as a metallized hole. In the double-sided panel and multi-layered panel, in order to communicate printed conductors between various layers, a common hole (i.e., a via hole) is provided at the intersection of wires to be connected at each layer.

In an arrangement of the present disclosure, the via hole platform of the SD layer at least partially overlaps with the via hole platform above the gate layer (in the GI layer). An SD layer hole (hereinafter referred to as a first via hole) having a diameter a may be formed on the via hole platform of the SD layer by, for example, wet etching. It should be noted that although only one first via hole is shown in FIG. 4, the number of first via holes may be set according to requirements, which will not be limited in the present disclosure.

In the arrangement of the present disclosure, size of the diameter a of the first via hole depends on the exposure accuracy, and generally, a size of 5±2 μm can be achieved. Specifically, the size of diameter a can be determined according to customer requirements, wiring and the like.

It should be noted that since the SD layer is generally a metal layer, wet etching may be employed, but the present disclosure is not limited thereto.

With continued reference to FIG. 3, trace of the SD layer may be appropriately widened compared to the related art shown in FIG. 1. Similarly, the so-called “appropriately widened” needs to be designed according to the actual situation. For example, the anti-ESD capability of the array substrate and the ESD requirements thereof may be considered, on one hand. On the other hand, the UV transmittance requirement of the array substrate may also be considered.

In an exemplary arrangement, the thin film transistor is provided in the TFT-LCD GOA (gate driver on array) region. The arrangement of the present disclosure can reduce the number of via hole platforms of the TFT-LCD GOA region by disposing the via hole platform above the gate layer (in the GI layer) and the via hole platform of the SD layer at least partially overlapping regions of the SD layer and the gate layer in a manner of at least partially overlapping, thus increasing the UV transmittance of the GOA region.

The GOA technology is to integrate a gate drive on the array substrate, so as to omit additional drive such as a Chip On film (COF) disposed at the edge of the array substrate, thus facilitating miniaturization of the array substrate and reducing costs of material and manufacturing process.

A GOA circuit may be provided at an edge outside the display area (AA area) of the display panel, including a signal line SL and a plurality of GOA units. One GOA unit corresponds to one gate line on the array substrate, and an output end of each GOA unit is connected to one gate line, and is also connected to an input end of the GOA unit to which the next scanning gate line is connected. The array substrate may include more than two gate-driven GOA units; a transmission path between adjacent two GOA units is composed of a via hole and a gate metal layer or a source/drain metal layer; the array substrate is provided with a pixel matrix, a gate line and a data line, the GOA unit is a driving unit that supplies voltage to the respective connected gate lines according to timing; the previous GOA unit is connected to the gate electrode metal layer through the via hole on the array substrate, and the latter GOA unit is similarly connected through the via hole to the gate electrode metal layer, so that a transmission path is formed between these two GOA units. In a specific application process, a via hole may be connected to the source/drain metal layer to form a transmission path. The output end of each GOA unit is connected to a gate line connected to a row of pixels in the display area of the display panel, i.e., each GOA unit corresponds to a row of pixels of the TFT-LCD; in addition, the output end of each GOA unit is further connected to the input end of the next GOA unit through wires so as to turn on the next GOA unit. In the working process of the TFT-LCD, it is necessary to sequentially provide a gate driving voltage for each row of pixels, the GOA unit corresponding to each row of pixels needs to start working in sequence.

However, the solution of the arrangement of the present disclosure is not limited to the GOA region, a sealant (such as a sealing adhesive or a frame adhesive) coating region, it can be used whenever the gate layer and the SD layer need to be connected through a jump hole.

The array substrate provided by the arrangement of the present disclosure can reduce the number of jump hole platforms, improve the UV transmittance, shorten UV curing time and improve puncture by at least partially overlapping the via hole platform provided in the gate insulating layer above the gate insulating layer and the via hole platform in the source/drain layer.

FIG. 5 shows a top view of another array substrate in an exemplary arrangement of the present disclosure.

On the basis of the structure shown in FIG. 3, a passivation layer (PVX layer) is deposited on the SD layer. The passivation layer may be, for example, silicon nitride SiNx, but the disclosure is not limited thereto. At least one second via hole is formed on the passivation layer by via hole etching to expose the source/drain and the gate of the TFT.

In the arrangement shown in FIG. 5, at least one first via hole and at least one second via hole form a sleeve hole structure 510.

In arrangements of the present disclosure, by at least partially overlapping the via hole platform provided in the GI layer above the gate layer and the via hole platform in the SD layer, a first via hole is firstly formed on the SD layer, and then a second via hole is formed on the PVX layer, so as to form a sleeve hole structure.

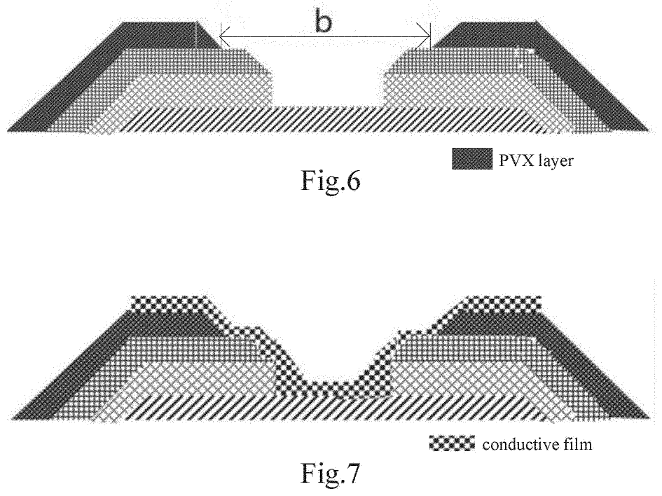

FIG. 6 shows a cross-sectional view based on the array substrate shown in FIG. 5.

As shown in FIG. 6, the second via hole formed on the PVX layer and the first via hole formed on the SD layer form a sleeve hole. The diameter b of the second via hole is larger than the diameter a of the first via hole. This is because the PVX layer deposits a non-metal film layer, density of which is smaller than that of the SD layer, so that b>a in the case of normal etching.

In the arrangement of the present disclosure, materials of the GI layer of the array substrate and the PVX layer may be the same, for example, which may be made of the same non-metal material. Thus, the via hole of the GI layer, i.e., at least one third via hole of the gate insulating layer, can be simultaneously etched using the condition of etching the via hole of the PVX layer. In other words, at least one third via hole of the GI layer and at least one second via hole of the PVX layer can be formed using the same mask plate. The PVX layer and the GI layer at the via hole are etched away by the same via hole process to expose the gate layer of the TFT.

With continued reference to the arrangement illustrated in FIG. 6, at least one first via hole and at least one second via hole are in the shape of an inverted round cone. In this arrangement, the inverted round cone facilitates electrical filling of the material.

In the arrangement of the present disclosure, by using the same mask plate for the PVX layer and the GI layer, at least one via hole in the GI layer and at least one PVX via hole of the PVX layer can be simultaneously formed through patterning process once, thus reducing manufacturing cost of the product.

The related art is to connect two layers of metal by adding a GI Mask between a Gate Mask and a SD Mask, and then self-depositing on the gate layer with the SD layer. In the arrangement of the present disclosure, in the case of achieving the same effect, the SD layer is punched in advance before deposition of the PVX layer by the SD MASK, and the via hole in the PVX layer and the via hole in the GI layer are simultaneously formed by a VIA MASK process. Connecting the SD layer metal directly to the gate layer through the via hole of the GI layer during deposition may save a GI Mask, so that the same product can shorten manufacturing time in the array production process.

FIG. 7 shows a cross-sectional view of still another array substrate in an exemplary arrangement of the present disclosure.

Based on the arrangement shown in FIG. 6, a conductive film is deposited on the PVX layer, the conductive film covering the SD layer and the sleeve hole structure for electrically connecting the SD layer and the gate layer. In the figure, the conductive film is exemplified by an indium tin oxide (ITO) layer, thus realizing skip-layer connection for the TFT, and connecting the source/drain and the gate of the TFT at the via hole.

Generally, there is a first ITO layer in the AA region of the array substrate (TFT substrate), so a layer for the TFT skip-layer connection of the TFT-LCD GOA region is called as a second ITO layer (2nd ITO), but the disclosure is not limited thereto.

In the arrangement of the present disclosure, the via hole platform in the GI layer above the gate layer and the via hole platform in the SD layer are at least partially overlapped by the SD Mask process, and the first via hole is formed in advance on the SD layer, and the second via hole is subsequently formed on the PVX layer so as to form a complete sleeve hole structure. The via hole platform of the gate layer is connected with the via hole platform of the SD layer by using the 2nd ITO, thus effectively reducing the number of via hole platforms, improving the UV transmittance of the GOA region in the TFT-LCD and improving puncture at the CELL end to some extent. At the same time, due to the reduced area of the via hole platform, trace of the gate layer and the SD layer can be appropriately widened, which is also helpful to improve ESD.

Moreover, in other exemplary arrangements of the present disclosure, the array substrate may further include other components. Therefore, the technical solution of adding more structures is also within the protection scope of the present disclosure.

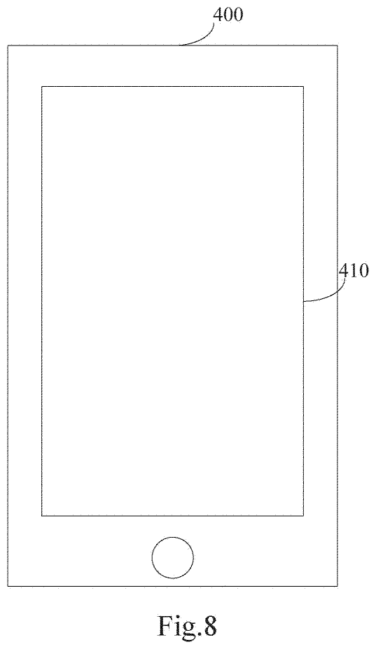

FIG. 8 shows a schematic view of a display device in an exemplary arrangement of the present disclosure.

As shown in FIG. 8, an arrangement of the present disclosure further provides a display device 400 including the array substrate as described in the above arrangements.

The display device 400 may be any display product or component such as a display panel, a mobile phone, a tablet computer, a television, a notebook computer, a digital photo frame, a navigator, and the like.

Referring to FIG. 8, the display device 400 may further include a display panel 410. The display panel 410 can be a flat display panel, such as a plasma panel, an organic light emitting diode (OLED) panel, or a thin film transistor liquid crystal display (TFT LCD) panel.

In an exemplary arrangement, the display device 400 may be a liquid crystal display device including an array substrate and a color film substrate disposed opposite to the array substrate, and the array substrate is a TFT-LCD array substrate. In a specific implementation process, the color film substrate may also be replaced by a transparent substrate, and the color film is disposed on the array substrate.

The display device may further be a box type OLED display device, including an opposite substrate disposed opposite to the array substrate and an organic light emitting material layer between the array substrate and the opposite substrate.

Since the display device provided by the present disclosure includes the above array substrate, the same technical problem can be solved and the same technical effects are obtained, which will not be further described herein.

Other arrangements of the present disclosure will be apparent to those skilled in the art after reading the specification and implementing the current disclosure. The present application is intended to cover any variations, purposes, or adaptations of the present disclosure, which are in accordance with the general principles of the present disclosure and include common general knowledge or conventional technical means in the art that are not disclosed in the present disclosure. The specification and arrangements are to be regarded as illustrative only, and the real scope and spirit of the present disclosure is defined by the attached claims.

1. An array substrate which comprises a plurality of thin film transistors, each of the plurality of thin film transistors comprising a gate layer, a source/drain layer and a gate insulating layer, the source/drain layer being provided above the gate layer, the gate insulating layer being provided between the gate layer and the source/drain layer, both the gate insulating layer and the source/drain layer comprising a via hole platform, wherein a via hole platform in a gate insulating layer and above gate layer of one of the plurality of thin film transistors is arranged to at least partially overlap a via hole platform in a source/drain layer of another of the plurality of thin film transistors.

2. The array substrate according to claim 1, wherein the via hole platform is a metal base.

3. The array substrate according to claim 1, wherein the via hole of the source/drain layer comprises at least one first via hole.

4. The array substrate according to claim 3, wherein the array substrate further comprises a passivation layer disposed on the source/drain layer, wherein the passivation layer comprises at least one second via hole, and the at least one first via hole and the at least one second via hole form a sleeve hole structure.

5. The array substrate according to claim 4, wherein a diameter of the at least one second via hole is larger than a diameter of the at least one first via hole.

6. The array substrate according to claim 1, wherein the gate insulating layer comprises at least one third via hole.

7. The array substrate according to claim 6, wherein the at least one third via hole and the at least one second via hole are formed of the same mask plate.

8. The array substrate according to claim 4, wherein the gate insulating layer and the passivation layer are made of the same non-metal material.

9. The array substrate according to claim 4, wherein the array substrate further comprises a conductive film covering the source/drain layer and the sleeve hole structure for electrically connecting the gate layer and the source/drain layer.

10. The array substrate according to claim 4, wherein the at least one first via hole and the at least one second via hole are in a shape of an inverted round cone.

11. The array substrate according to claim 5, wherein the at least one first via hole and the at least one second via hole are in a shape of an inverted round cone.

12. The array substrate according to claim 1, wherein the via hole platform in the gate insulating layer and above the gate layer of the one of the plurality of thin film transistors is arranged to completely overlap the via hole platform in the source/drain layer of the another of the plurality of thin film transistors.

13. The array substrate according to claim 1, wherein the thin film transistor is provided in a gate driver on array region of the array substrate.

14. The array substrate according to claim 1, wherein a number of the gate insulating layer is one or more.

15. The array substrate according to claim 14, wherein a number of the gate insulating layer is two, which comprises a SiO₂ film and a SiNx layer disposed on the SiO₂ film.

16. A display device comprising an array substrate which comprises a plurality of thin film transistors, each of the plurality of thin film transistors comprising a gate layer, a source/drain layer and a gate insulating layer, the source/drain layer being provided above the gate layer, the gate insulating layer being provided between the gate layer and the source/drain layer, both the gate insulating layer and the source/drain layer comprising a via hole platform, wherein a via hole platform in a gate insulating layer and above a gate layer of one of the plurality of thin film transistors is arranged to at least partially overlap a via hole platform in a source/drain layer of another of the plurality of thin film transistors.
